(19) United States
(12) Patent Application Publication
(10) Pub. No.: US 2026/0035583 A1
(43) Pub. Date: Feb. 5, 2026

(54) IN-SITU THERMALLY ACTIVATED IONIC INK, AND PREPARATION METHOD AND APPLICATION THEREOF

(71) Applicant: Guangdong University of Technology, Guangzhou (CN)

(72) Inventors: Yu ZHANG, Guangzhou (CN); Weiliang XIE, Guangzhou (CN); Yutao LI, Guangzhou (CN); Jia LENG, Guangzhou (CN); Guannan YANG, Guangzhou (CN); Chengqiang CUI, Guangzhou (CN)

(21) Appl. No.: 19/356,160

(22) Filed: Oct. 12, 2025

(30) Foreign Application Priority Data
Jan. 2, 2025 (CN) 202510001832.3

(51) Int. Cl. C09D 11/52; C09D 7/80; C09D 11/033; C09D 11/037; H05K 3/10; H05K 3/12

(52) U.S. Cl. CPC C09D 11/52; C09D 7/80; C09D 11/033; C09D 11/037; H05K 3/105; H05K 3/1216

(57) ABSTRACT

A preparation method of a green in-situ thermally activated ionic ink, in which a precursor is ground, where the precursor is not a metallic elementary substance, and is a copper-containing precursor, a silver-containing precursor, a nickel-containing precursor, a cobalt-containing precursor and/or a gold-containing precursor; the ground precursor is mixed with a first solvent to prepare the in-situ thermally activated ionic ink, where the first solvent is a reductive solvent that does not react with the precursor at room temperature.

### CROSS-REFERENCE TO RELATED APPLICATIONS

This application claims the benefit of priority from Chinese Patent Application No. 202510001832.3, filed on Jan. 2, 2025. The content of the aforementioned application, including any intervening amendments thereto, is incorporated herein by reference in its entirety.

### TECHNICAL FIELD

This application relates to electronic materials, and more particularly to an in-situ thermally activated ionic ink, and a preparation method and application thereof.

### BACKGROUND

The exiting preparation of conductive inks generally struggles with serious solvent pollution, high toxicity and complicated process. Moreover, the wastewater discharge will severely destroy the environment. In this regard, it is urgently needed to develop an environmentally-friendly conductive ink and a simplified preparation thereof to achieve the sustainable and healthy development of the printed electronics industry.

The existing techniques for preparing the micron/nano metal particle-containing conductive ink mainly involve two steps: (1) micron/nano metal particles are synthesized via physical or chemical methods, purified to remove excess impurities, dried and stored for use; (2) the prepared micron/nano metal particles are dispersed into a solvent, and mixed uniformly with additives to produce the conductive ink.

The above preparation process involves preparation, purification and drying of the micron/nano metal particles, and mixing of the micron/nano metal particles with the solvent and additives to prepare the conductive ink, leading to cumbersome operation, serious time consumption, and high cost.

### SUMMARY

A first object of the present disclosure is to provide a preparation method of an in-situ thermally activated ionic ink, which is performed by mixing at room temperature, and involves neither the preparation of micron/nano metal particles nor the introduction of organic impurities (difficult to remove at high temperatures) such as resins, cellulose, and cellulose derivatives that are conventionally used in the ink preparation, thereby significantly shortening the preparation time and making it more convenient and efficient.

A second object of the present disclosure is to provide an in-situ thermally activated ionic ink prepared by the aforementioned method, which is an environmentally-friendly conductive ink without pollution and toxicity.

A third object of the present disclosure is to provide a method of fabricating a printed electronic element. Specifically, the prepared in-situ thermally activated ionic ink can be directly coated on a substrate surface and sintered, thereby achieving the integrated generation and sintering of the micron/nano metal particles. The present disclosure addresses the problem of cumbersome operation, large time consumption and high cost in the existing preparation processes involving preparation of the micron/nano metal particles and preparation of the conductive ink.

In a first aspect, this application provides a method of preparing an in-situ thermally activated ionic ink, comprising:
(1) grinding a precursor, wherein the precursor is not a metallic elementary substance, and is selected from the group consisting of a copper-containing precursor, a silver-containing precursor, a nickel-containing precursor, a cobalt-containing precursor, a gold-containing precursor and a combination thereof; and
(2) mixing a ground precursor with a first solvent to prepare the in-situ thermally activated ionic ink, wherein the first solvent is a reductive solvent that does not react with the precursor at room temperature.

In an embodiment, the copper-containing precursor is a copper ion-containing inorganic substance, a copper ion-containing metal-organic substance or a combination thereof;
the silver-containing precursor is a silver ion-containing inorganic substance, a silver ion-containing metal-organic substance or a combination thereof;
the nickel-containing precursor is a nickel ion-containing inorganic substance, a nickel ion-containing metal-organic substance or a combination thereof;
the cobalt-containing precursor is a cobalt ion-containing inorganic substance, a cobalt ion-containing metal-organic substance or a combination thereof; and
the gold-containing precursor is a gold ion-containing inorganic substance, a gold ion-containing metal-organic substance or a combination thereof.

In an embodiment, the copper ion-containing metal-organic substance is selected from the group consisting of copper acetate, copper formate, cupric acetylacetonate, copper neodecanoate, copper decanoate, copper gluconate, copper citrate, copper oxalate and a combination thereof;
the silver ion-containing metal-organic substance is selected from the group consisting of silver formate, silver acetate, silver citrate, silver acetylacetonate, silver fatty acid salt and a combination thereof;
the nickel ion-containing metal-organic substance is selected from the group consisting of nickel formate, nickel acetate, nickel oxalate and a combination thereof;
the cobalt ion-containing metal-organic substance is cobalt acetate; and
the gold ion-containing metal-organic substance is selected from the group consisting of gold formate, gold acetate and a combination thereof.

In an embodiment, the first solvent is selected from the group consisting of glycerol, ethyl acetate, polyethylene glycol and a combination thereof.

In an embodiment, the step (2) is performed through steps of:
mixing the ground precursor with the first solvent to obtain a mixture; and
adding a second solvent to the mixture to obtain the in-situ thermally activated ionic ink;
wherein the second solvent is a 20% or less of a total weight of the mixture; and
the second solvent is selected from the group consisting of diethylene glycol, ethanol, ethylene glycol, water and a combination thereof.

In some embodiments, a weight ratio of the ground precursor to the first solvent is 0.2-1:1.

The in-situ thermally activated ionic ink is prepared by the aforementioned method.

A method of fabricating a printed electronic element, comprising:
preparing an in-situ thermally activated ionic ink through the aforementioned method;
coating the in-situ thermally activated ionic ink on a surface of the substrate to form a conductive ink film; and
sintering the substrate coated with the conductive ink film in a sintering furnace to form a conductive film on the substrate, so as to produce the printed electronic element.

In an embodiment, the method further comprises:
subjecting the substrate to plasma treatment prior to coating of the in-situ thermally activated ionic ink on the surface of the substrate.

In an embodiment, a sintering temperature is 120-350° C., and a sintering time is 10-120 min;
a sintering atmosphere is selected from the group consisting of an air atmosphere, a nitrogen atmosphere, an argon atmosphere, a hydrogen atmosphere and a combination thereof; and
a material of the substrate is selected from the group consisting of polyimide, polyethylene terephthalate, silicon, aluminum plate, aluminum foil, copper foil, silicon carbide, gallium nitride, stainless steel and glass.

Compared to the prior art, the present disclosure has the following beneficial effects.

Regarding the method provided herein for preparing the in-situ thermally active ionic ink, it does not require the preparation of micron/nano metal particles and the introduction of resins or ethyl cellulose that are commonly used in the traditional ink preparation. Moreover, the preparation method provided herein also avoids the introduction of organic impurities that are difficult to be removed at high temperature, and has significantly shortened preparation time. In the application of printed electronics, the in-situ thermally activated ionic ink obtained by the preparation method can be activated only during sintering to generate the conductive metal particles, thereby forming the conductive film with superior electrical conductivity and resistivity.

### BRIEF DESCRIPTION OF THE DRAWINGS

In order to make technical solutions in the present disclosure clearer, the accompanying drawings needed in the description of the embodiments of the present disclosure will be briefly described below. Obviously, presented in the accompanying figures are merely some embodiments of the present disclosure. Based on these accompanying figures, other accompanying figures can be obtained by those skilled in the art without paying any creative efforts.

FIG. 1 shows a flow chart of the fabrication of a printed electronic element with a green in-situ thermally activated ionic ink according to an embodiment of the present disclosure;

FIG. 2 schematically shows the preparation of the in-situ thermally activated ionic ink according to an embodiment of the present disclosure;

FIG. 3 schematically shows an imprinting angle between a doctor blade and a screen in the printing step according to an embodiment of the present disclosure;

FIG. 4 shows an X-ray diffraction (XRD) pattern of a copper film after sintering in Example 1; and

FIG. 5 is a scanning electron microscopy (SEM) image of the copper film after sintering in Example 1.

### DETAILED DESCRIPTION OF EMBODIMENTS

The technical solutions in the embodiments of the present disclosure will be described clearly and completely below in combination with the accompanying drawings. Obviously, the described embodiments are merely some embodiments of the present disclosure and not all the embodiments. Based on the embodiments in the present disclosure, all other embodiments obtained by those skilled in the art without paying creative efforts shall fall within the scope of the present disclosure. In addition, it should be understood that the specific embodiments described herein are only for illustrating and explaining the present disclosure, and are not intended to limit the present disclosure.

As used herein, unless otherwise specified, orientation terms such as “upper” and “lower” generally refer to the actual operational orientation of the device during use, specifically corresponding to the direction shown in the accompanying drawings; the terms such as “inner” and “outer” are defined relative to the contour of the referred devices. Moreover, as used herein, the term “comprise” means “include but not limited to”. The terms “first”, “second”, “third”, etc. are merely illustrative and indicative, rather than indicating or implying the quantity or order of the referred elements.

As used herein, “and/or” is used to describe a relationship of associated objects, indicating the inclusion of three solutions; for example, A and/or B includes A, B and a combination thereof.

As used herein, “at least one” refers to one or more, and “more than one” refers to two or more; “at least one”, “at least one of the following”, or similar expressions, refer to any combination of these items, including any combination of single or plural items. For example, “at least one of a, b, or c,” and “at least one of a, b, and c,” both include “a, b, c, a-b (i.e., a and b), a-c, b-c, and a-b-c”, where a, b, and c can be single or plural, respectively.

Various embodiments of the present disclosure can be in the form of a range; it should be understood that the description in the form of the range is provided only for convenience and simplicity and is not intended to limit the present disclosure; accordingly, it should be noted that the description of the range has specifically disclosed all possible sub-ranges as well as a single value within the range. For example, the description of the range of 1-6 should be considered to specifically disclose sub-ranges, such as 1-3, 1-4, 1-5, 2-4, 2-6, 3-6, etc., as well as a single number within the range, such as 1, 2, 3, 4, 5, and 6, which applies regardless of the range. In addition, whenever a numerical range is used herein, it refers to including any quoted number (fraction or integer) within the indicated range.

The technical solutions of the present disclosure are described as follows.

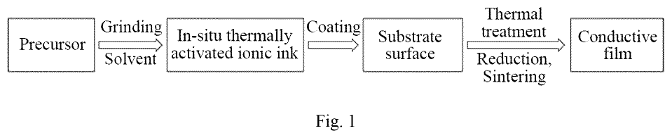

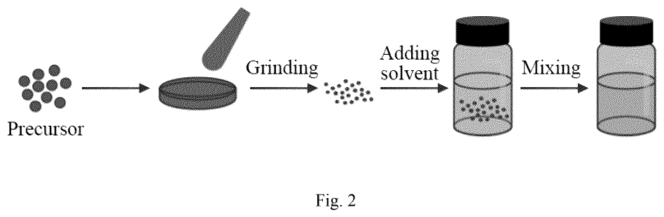

Referring to FIGS. 1-2, the present disclosure provides a method of preparing an in-situ thermally activated ionic ink, including:
(1) a precursor is ground, where the precursor is not a metallic elementary substance, and is selected from the group consisting of a copper-containing precursor, a silver-containing precursor, a nickel-containing precursor, a cobalt-containing precursor, a gold-containing precursor and a combination thereof; and
(2) the ground precursor is mixed with a first solvent to prepare the in-situ thermally activated ionic ink, where the first solvent is a reductive solvent that does not react with the precursor at room temperature.

The present disclosure provides the method of preparing the in-situ thermally activated ionic ink, which is performed by mixing at room temperature, and involve neither the preparation of micron/nano metal particles nor the introduction of organic impurities (difficult to remove at high temperatures) such as resins, cellulose, and cellulose derivatives that are conventionally used in the ink preparation, thereby significantly shortening the preparation time and making it more convenient and efficient. The first solvent simultaneously plays a role as solvent and reductive agent, and does not react with the precursor at room temperature, thereby achieving the integrated generation and sintering of the micron/nano metal particles through the high-temperature treatment. Moreover, the oxidation of the oxidation-sensitive metal conductive ink can be avoided during the preparation and storage processes, thereby avoiding attenuating the conductivity of the conductive film. The present disclosure effectively addresses the problems of cumbersome operation, long production cycle and high cost in the existing preparation of metal-based conductive inks (involving preparation of micron/nano metal particles).

In an embodiment, the precursor is ground into particles with a particle size of 100 nm-10 μm.

In an embodiment, the copper-containing precursor is a copper ion-containing inorganic substance, a copper ion-containing metal-organic substance or a combination thereof;
the silver-containing precursor is a silver ion-containing inorganic substance, a silver ion-containing metal-organic substance or a combination thereof;
the nickel-containing precursor is a nickel ion-containing inorganic substance, a nickel ion-containing metal-organic substance or a combination thereof;
the cobalt-containing precursor is a cobalt ion-containing inorganic substance, a cobalt ion-containing metal-organic substance or a combination thereof; and
the gold-containing precursor is a gold ion-containing inorganic substance, a gold ion-containing metal-organic substance or a combination thereof.

In some embodiments, the copper ion-containing inorganic substance is selected from the group consisting of cupric oxide, copper oxide, cupric hydroxide and a combination thereof;
the silver ion-containing inorganic substance is selected from the group consisting of silver oxide, silver carbonate and a combination thereof;
the nickel ion-containing inorganic substance is selected from the group consisting of nickel oxide, nickel hydroxide, nickel carbonate and a combination thereof;
the cobalt ion-containing inorganic substance is selected from the group consisting of cobalt hydroxide, cobalt carbonate, cobalt oxide and a combination thereof; and
the gold ion-containing inorganic substance is gold carbonate.

In an embodiment, the copper ion-containing metal-organic substance is selected from the group consisting of copper acetate, copper formate, cupric acetylacetonate, copper neodecanoate, copper decanoate, copper gluconate, copper citrate, copper oxalate and a combination thereof;
the silver ion-containing metal-organic substance is selected from the group consisting of silver formate, silver acetate, silver citrate, silver acetylacetonate, silver fatty acid salt and a combination thereof;
the nickel ion-containing metal-organic substance is selected from the group consisting of nickel formate, nickel acetate, nickel oxalate and a combination thereof;
the cobalt ion-containing metal-organic substance is cobalt acetate; and
the gold ion-containing metal-organic substance is selected from the group consisting of gold formate, gold acetate and a combination thereof.

In an embodiment, the first solvent is selected from the group consisting of glycerol, ethyl acetate, polyethylene glycol and a combination thereof. The first solvent is a mildly reductive and environmentally-friendly solvent without pollution and toxicity.

In an embodiment, the step (2) is performed through steps of mixing the ground precursor with the first solvent to obtain a mixture, and adding a second solvent to the mixture to obtain the in-situ thermally activated ionic ink, where the second solvent is 20% or less of a total weight of the mixture. The second solvent is added to the mixture to adjust a viscosity thereof.

In an embodiment, the second solvent is selected from the group consisting of diethylene glycol, ethanol, ethylene glycol and, water and a combination thereof.

In some embodiments, a weight ratio of the ground precursor to the first solvent is 0.2-1:1. The weight ratio is to facilitate mixing and ensure a formation of the conductive film after coating, thereby preventing the precursor from incompletely reducing and affecting conductivity performance.

The present disclosure provides an in-situ thermally activated ionic ink, where the in-situ thermally activated ionic ink is prepared by the aforementioned method.

The method of fabricating a printed electronic element, including:
preparing an in-situ thermally activated ionic ink through the method according to any one of the embodiments;
coating the in-situ thermally activated ionic ink on a surface of the substrate to form a conductive ink film; and
sintering the substrate coated with the conductive ink film in a sintering furnace to form a conductive film on the substrate, so as to produce the printed electronic element.

Regarding the method provided herein for preparing the green in-situ thermally active ionic ink, the integrated generation and sintering of the micron/nano metal particles is achieved without the preparation of micron/nano metal particles. Moreover, the oxidation of the oxidation-sensitive metal conductive ink can be avoided during the preparation and storage processes. In the application of printed electronics, the first solvent is mixed uniformly with the precursor to prepare the in-situ thermally activated ionic ink. Specifically, the prepared in-situ thermally activated ionic ink can be directly coated on the substrate surface and sintered, thereby achieve the integrated generation and sintering of the micron/nano metal particles. The present disclosure addresses the problem of cumbersome operation, large time consumption and high cost in the existing preparation processes involving preparation of the micron/nano metal particles and preparation of the conductive ink.

In an embodiment, the substrate surface is subjected to plasma treatment prior to coating of the in-situ thermally activated ionic ink on the substrate surface. Mild thermal decomposition, softening, or reorganization may occur on the substrate surface. These processes can change microstructures of the substrate surface, forming tiny protrusions, depressions and textures, thereby increasing surface roughness. In view of this, the plasma treatment is performed prior to coating of the in-situ thermally activated ionic ink on the substrate surface. After the plasma treatment, active groups are generated on the substrate surface; and the first solvent with reducibility has hydroxyl groups such that the active groups can enhance a polarity of the substrate surface, making it more easily wet. Good wettability facilitates the in-situ thermally activated ionic ink spreading better on the substrate surface. Meanwhile, the in-situ thermally activated ionic ink is accelerated to diffuse due to high temperature, so as to penetrate and interweave into a rough interface of the substrate. Under high temperature, the thermal expansion of the substrate becomes more pronounced. Therefore, after cooling, the substrate shrinks, forming a strong mechanical bond with the conductive film, thereby effectively enhancing an adhesion.

In an embodiment, in the fabrication method of the printed electronic element, a sintering temperature is 120-350° C., and a sintering time is 10-120 min. A sintering atmosphere is selected from the group consisting of an air atmosphere, a nitrogen atmosphere, an argon atmosphere, a hydrogen atmosphere and a combination thereof. A material of the substrate is selected from the group consisting of polyimide, polyethylene terephthalate, silicon, aluminum plate, aluminum foil, copper foil, silicon carbide, gallium nitride, stainless steel, glass and a combination thereof.

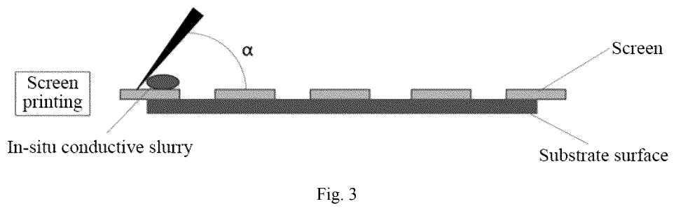

In an embodiment, the in-situ thermally activated ionic ink is coated on the substrate surface by screen printing, specifically referring to a schematic diagram of an imprinting angle between a doctor blade and a screen in the coating step as shown in FIG. 3.

In an embodiment, the imprinting angle between the doctor blade and the screen in the coating step is controlled within a range of 40-60°, thereby facilitating uniformity and completeness of printed layer.

### Example 1

### (1) Preparation of an In-Situ Thermally Activated Ionic Ink

Copper acetate and copper oxide precursors were respectively ground well into copper acetate and copper oxide particles with a particle size of 500 nm-1 μm. After grinding, the ground copper acetate and copper oxide particles were mixed with glycerol to give a mixture, where a weight ratio of the ground copper acetate particles to the ground copper oxide particles to the glycerol was 1:1:3. The mixture was placed in a blender machine, mixed twice, followed by adding diglycol, where the diglycol was 5% of a total weight of the mixture. After mixing well, an in-situ thermally activated ionic ink was obtained.

### (2) Coating

A polyimide substrate was cleaned through steps of: first, the polyimide substrate was cleaned with deionized water in an ultrasonic cleaner for 20 min to remove dust and impurities on the substrate surface; then, the substrate was finally cleaned with anhydrous ethanol for 15 min, placed in a drying oven at 60° C., dried, and subjected to a plasma treatment for 2 min, followed by coating of the in-situ thermally activated ionic ink on the substrate surface by screen printing.

### (3) Sintering

The substrate coated with the in-situ thermally activated ionic ink was placed in a rapid annealing furnace and sintered at 300° C. under an atmosphere of 95% argon and 5% hydrogen for 90 min.

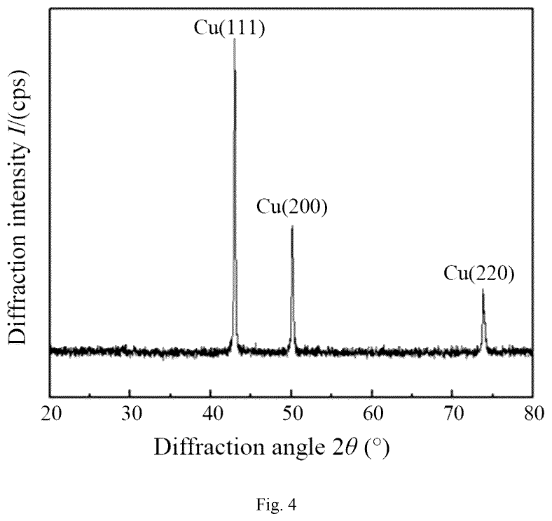

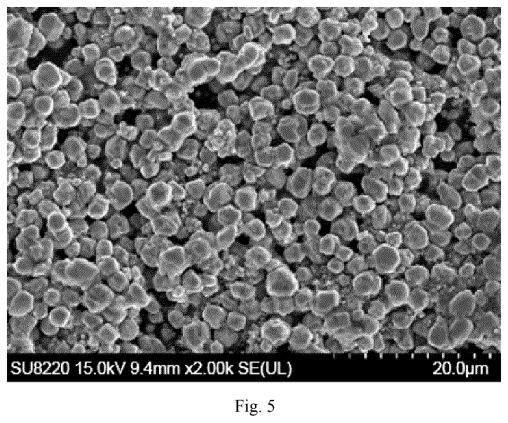

A conductive film with an adhesion of ASTM 5B and a resistivity of 5.6μΩ · cm was obtained by the sintering. An X-ray diffraction (XRD) pattern of a copper film after sintering was shown in FIG. 4. A scanning electron microscopy (SEM) image of the copper film after sintering in Example 1 was shown in FIG. 5.

### Example 2

### (1) Preparation of an In-Situ Thermally Activated Ionic Ink

Copper hydroxide precursor was ground well into copper hydroxide particles with a particle size of 300-800 nm. After grinding, the ground copper hydroxide particles were mixed with a first solvent of polyethylene glycol 600 and glycerol to give a mixture, where a weight ratio of the ground copper hydroxide particles to the polyethylene glycol 600 to the glycerol was 3:1:4. The mixture was placed in a blender machine, mixed three times, followed by adding ethylene glycol, where the ethylene glycol was 5% of a total weight of the mixture. After mixing well, an in-situ thermally activated ionic ink was obtained.

### (2) Coating

A glass substrate was cleaned through steps of: first, the glass substrate was cleaned with deionized water in an ultrasonic cleaner for 15 min to remove dust and impurities on the substrate surface; then, the substrate was finally cleaned with anhydrous ethanol for 5 min, placed in a drying oven at 60° C., dried, and subjected to a plasma treatment for 2 min, followed by coating of the in-situ thermally activated ionic ink on the substrate surface by screen printing.

### (3) Sintering

The substrate coated with the in-situ thermally activated ionic ink was placed in a sintering furnace and sintered at 320° C. under an air atmosphere for 30 min to give a conductive film with an adhesion of ASTM 4B and a resistivity of 13.2 μΩ·cm.

### Example 3

### (1) Preparation of an In-Situ Thermally Activated Ionic Ink

Gold acetate precursor was ground well into gold acetate particles with a particle size of 1-3 μm. After grinding, the gold acetate particles were mixed with a first solvent of glycerol, diglycol and ethanol, where a weight ratio of the gold acetate particles to the glycerol to the diglycol to the ethanol was 3:5:1:1 to give a mixture. The mixture was placed in a blender machine, mixed twice, followed by adding ethylene glycol, where the ethylene glycol was 5% of a total weight of the mixture. After mixing well, an in-situ thermally activated ionic ink was obtained.

### (2) Printing

A glass substrate was cleaned as follows: first, the glass substrate was cleaned with deionized water in an ultrasonic cleaner for 15 min to remove dust and impurities on the substrate surface; then, the substrate was finally cleaned with anhydrous ethanol for 15 min, placed in a drying oven at 60° C., dried, and subjected to a plasma treatment for 2 min, followed by coating of the in-situ thermally activated ionic ink on the substrate surface by screen printed.

### (3) Sintering

The substrate coated with the in-situ thermally activated ionic ink was placed in a sintering furnace and sintered at 300° C. under an air atmosphere for 60 min to give a conductive film with an adhesion of ASTM 4B and a resistivity of 17.8 μΩ·cm.

### Example 4

### (1) Preparing an In-Situ Thermally Activated Ionic Ink

Silver carbonate precursor was ground well into silver carbonate particles with a particle size of 3-10 μm. After grinding, the silver carbonate particles were mixed with a first solvent of glycerol and ethylene glycol to give a mixture, where a weight ratio of the silver carbonate particles to the glycerol to the ethylene glycol was 4:5:1. The mixture was placed in a blender machine and mixed three times. After mixing well, an in-situ thermally activated ionic ink was obtained.

### (2) Coating

A polyimide substrate was cleaned through steps of: first, the polyimide substrate was cleaned with deionized water in an ultrasonic cleaner for 15 min to remove dust and impurities on the substrate surface; then, the substrate was finally cleaned with anhydrous ethanol for 15 min, placed in a drying oven, dried, and subjected to a plasma treatment for 2 min followed by coating of the in-situ thermally activated ionic ink on the substrate surface.

### (3) Sintering

The substrate coated with the in-situ thermally activated ionic ink was placed in a sintering furnace and sintered at 260° C. under an air atmosphere for 30 min to give a conductive film with an adhesion of ASTM 4B and a resistivity of 26.5 μΩ·cm.

### Comparative Example 1

### (1) Preparation of Copper Nanoparticles

Copper sulfate precursor was reduced by hydrazine hydrate to form a copper nanoparticles suspension in the ethylene glycol solution. The copper nanoparticles suspension was centrifugated, washed, purified, dried and resuspended for many times to give copper nanoparticles with a particle size of 100-200 nm.

### (2) Preparation of a Conductive Ink

The copper nanoparticles were dispersed in a mixed solvent of propylene glycol and ethanol to prepare a nano-copper conductive ink.

### (3) Coating

The nano-copper conductive ink was coated on the polyimide substrate.

### (4) Sintering

The polyimide substrate coated with the nano-copper conductive ink was sintered at 260° C. under a nitrogen atmosphere for 30 min to give a nano-copper film with a resistivity of 127.3 μΩ·cm and an adhesion of ASTM 2B.

Compared with Comparative example 1, the Examples 1˜4 of the present disclosure involve neither purification nor drying of metal nanoparticles to prevent copper particles from reacting with oxygen during the preparation of the copper nanoparticles, while maintaining conductive performance and using environmentally-friendly solvents and reductive reagents instead of toxic reagents.

### Comparative Example 2

### (1) Preparation of Silver Nanoparticles

Silver nitrate precursor was reduced by sodium borohydride to form a silver nanoparticles suspension in an ethanol solution. The silver nanoparticles suspension was purified and dried for many times to give silver nanoparticles with a particle size of 50-100 nm.

### (2) Preparation of a Conductive Ink

The silver nanoparticles were dispersed in a mixed solvent of ethylene glycol and ethanol, followed by adding ethyl cellulose to prepare a composition silver-conductive ink.

### (3) Coating

The composition silver-conductive ink was coated on the polyimide substrate.

### (4) Sintering

The polyimide substrate coated with the composition silver-conductive ink was sintered at 240° C. under an air atmosphere for 30 min to give a silver film with a resistivity of 87.7 μΩ·cm and an adhesion of ASTM 4B.

### Comparative Example 3

### (1) Preparing an Ionic Ink

Copper acetate and copper oxide precursors were respectively ground well into copper acetate and copper oxide particles with a particle size of 500 nm-1 μm. After grinding, the copper acetate and copper oxide particles were mixed with glycerol to give a mixture, where a weight ratio of the copper acetate particles to the copper oxide particles to the glycerol was 0.1:1. The mixture was placed in a blender machine, mixed twice, followed by adding diglycol, where the diglycol was 5% of a total weight of the mixture. After mixing well, an ionic ink was obtained.

### (2) Coating

A polyimide substrate was cleaned through steps of: first, the polyimide substrate was cleaned with deionized water in an ultrasonic cleaner for 20 min to remove dust and impurities on the substrate surface; then, the substrate was finally cleaned with anhydrous ethanol for 15 min, placed in a drying oven at 60° C., dried, and subjected to a plasma treatment for 2 min, followed by coating of the ionic ink on the substrate surface by screen printing.

### (3) Sintering

The substrate coated with the ionic ink was placed in a rapid annealing furnace and sintered at 300° C. under an atmosphere of 95% argon and 5% hydrogen for 90 min to give a conductive film with an adhesion of ASTM 2B and a resistivity of 175.9 μΩ·cm was obtained.

### Comparative Example 4

### (1) Preparation of an Ionic Ink

Copper acetate and copper oxide precursors were respectively ground well into copper acetate and copper oxide particles with a particle size of 500 nm-1 μm. After grinding, the copper acetate and copper oxide particles were mixed with glycerol to give a mixture, where a weight ratio of the copper acetate particles to the copper oxide particles to the glycerol was 1.5:1. The mixture was placed in a blender machine, mixed twice, followed by adding diglycol, where the diglycol was 5% of a total weight of the mixture. After mixing well, an ionic ink was obtained.

### (2) Coating

A polyimide substrate was cleaned through steps of: first, the polyimide substrate was cleaned with deionized water in an ultrasonic cleaner for 20 min to remove dust and impurities on the substrate surface; then, the substrate was finally cleaned with anhydrous ethanol for 15 min, placed in a drying oven at 60° C., dried, and subjected to a plasma treatment for 2 min, followed by coating of the ionic ink on the substrate surface by screen printing.

### (3) Sintering

The substrate coated with the ionic ink was placed in a rapid annealing furnace and sintered at 300° C. under an atmosphere of 95% argon and 5% hydrogen for 90 min to give a conductive film with an adhesion of ASTM 3B and a resistivity of 56.3 μΩ·cm.

Parameter comparison between Examples 1-4 and Comparative examples 1-4

| | Adhesion | Resistivity | Hazardous/Toxic |
|---|---|---|---|
| Group | (ASTM) | (μΩ · cm) | reagents used |
| Example 1 | 5B | 5.6 | no |
| Example 2 | 4B | 13.2 | no |
| Example 3 | 4B | 17.8 | no |
| Example 4 | 4B | 26.5 | no |
| Comparative | 2B | 127.3 | hydrazine |
| example 1 | | | hydrate |
| Comparative | 4B | 87.7 | sodium |
| example 2 | | | borohydride |
| Comparative | 2B | 175.9 | no |
| example 3 | | | |
| Comparative | 3B | 56.3 | no |
| example 4 | | | |

As known from the Examples of the present disclosure and Comparative examples, the performances of the ionic ink provided herein are similar or superior to those of conventional metal conductive inks, exhibiting excellent practicability and applicability. The present disclosure not only simplifies the preparation procedure, but also achieves both environmental sustainability and industrial scalability.

What is claimed is:

1. A method of preparing an in-situ thermally activated ionic ink, comprising:
(1) grinding a precursor, wherein the precursor is not a metallic elementary substance, and is selected from the group consisting of a copper-containing precursor, a silver-containing precursor, a nickel-containing precursor, a cobalt-containing precursor, a gold-containing precursor and a combination thereof; and
(2) mixing a ground precursor with a first solvent to prepare the in-situ thermally activated ionic ink, wherein the first solvent is a reductive solvent that does not react with the precursor at room temperature.

2. The method according to claim 1, wherein the copper-containing precursor is a copper ion-containing inorganic substance, a copper ion-containing metal-organic substance or a combination thereof;
the silver-containing precursor is a silver ion-containing inorganic substance, a silver ion-containing metal-organic substance or a combination thereof;
the nickel-containing precursor is a nickel ion-containing inorganic substance, a nickel ion-containing metal-organic substance or a combination thereof;
the cobalt-containing precursor is a cobalt ion-containing inorganic substance, a cobalt ion-containing metal-organic substance or a combination thereof; and
the gold-containing precursor is a gold ion-containing inorganic substance, a gold ion-containing metal-organic substance or a combination thereof.

3. The method according to claim 2, wherein the copper ion-containing metal-organic substance is selected from the group consisting of copper acetate, copper formate, cupric acetylacetonate, copper neodecanoate, copper decanoate, copper gluconate, copper citrate, copper oxalate and a combination thereof;
the silver ion-containing metal-organic substance is selected from the group consisting of silver formate, silver acetate, silver citrate, silver acetylacetonate, silver fatty acid salt and a combination thereof;
the nickel ion-containing metal-organic substance is selected from the group consisting of nickel formate, nickel acetate, nickel oxalate and a combination thereof;
the cobalt ion-containing metal-organic substance is cobalt acetate; and
the gold ion-containing metal-organic substance is selected from the group consisting of gold formate, gold acetate and a combination thereof.

4. The method according to claim 1, wherein the first solvent is selected from the group consisting of glycerol, ethyl acetate, polyethylene glycol and a combination thereof.

5. The method according to claim 1, wherein the step (2) is performed through steps of:
mixing the ground precursor with the first solvent to obtain a mixture; and
adding a second solvent to the mixture to obtain the in-situ thermally activated ionic ink;
wherein the second solvent is 20% or less of a total weight of the mixture; and
the second solvent is selected from the group consisting of diethylene glycol, ethanol, ethylene glycol, water and a combination thereof.

6. The method according to claim 1, wherein a weight ratio of the ground precursor to the first solvent is 0.2-1:1.

7. An in-situ thermally activated ionic ink, wherein the in-situ thermally activated ionic ink is prepared by the method according to claim 1.

8. A method of fabricating a printed electronic element, comprising:
preparing an in-situ thermally activated ionic ink through the method according to claim 1;
coating the in-situ thermally activated ionic ink on a surface of the substrate to form a conductive ink film; and
sintering the substrate coated with the conductive ink film in a sintering furnace to form a conductive film on the substrate, so as to produce the printed electronic element.

9. The method according to claim 8, further comprising:
subjecting the substrate to plasma treatment prior to coating of the in-situ thermally activated ionic ink on the surface of the substrate.

10. The method according to claim 8, wherein a sintering temperature is 120-350° C., and a sintering time is 10-120 min;
a sintering atmosphere is selected from the group consisting of an air atmosphere, a nitrogen atmosphere, an argon atmosphere, a hydrogen atmosphere and a combination thereof; and
a material of the substrate is selected from the group consisting of polyimide, polyethylene terephthalate, silicon, aluminum plate, aluminum foil, copper foil, silicon carbide, gallium nitride, stainless steel and glass.
